(19) United States
(12) Patent Application Publication
(10) Pub. No.: US 2024/0312974 A1
(43) Pub. Date: Sep. 19, 2024

(54) SEMICONDUCTOR PACKAGE

(71) Applicant: SAMSUNG ELECTRONICS CO., LTD., SUWON-SI (KR)

(72) Inventors: KYOUNGLIM SUK, SUWON-SI (KR); JIHWANG KIM, SUWON-SI (KR); SUCHANG LEE, SUWON-SI (KR); JAEGWON JANG, SUWON-SI (KR)

(21) Appl. No.: 18/497,672

(22) Filed: Oct. 30, 2023

(30) Foreign Application Priority Data
Mar. 16, 2023 (KR) 10-2023-0034304

(51) Int. Cl. H01L 25/18; H01L 23/00; H01L 23/31; H01L 23/367; H01L 23/498; H10B 80/00

(52) U.S. Cl. CPC H01L 25/18; H01L 23/3107; H01L 23/367; H01L 23/49811; H01L 23/49822; H01L 23/49838; H01L 24/08; H01L 24/16; H01L 24/32; H01L 24/48; H01L 24/73; H10B 80/00; H01L 23/49866; H01L 2224/08145; H01L 2224/16148; H01L 2224/16227; H01L 2224/16238; H01L 2224/32145; H01L 2224/32225; H01L 2224/32245; H01L 2224/48145; H01L 2224/48227; H01L 2224/73204; H01L 2224/73253; H01L 2224/73265; H01L 2924/1431; H01L 2924/1436; H01L 2924/1437; H01L 2924/1438; H01L 2924/3511

(57) ABSTRACT

A semiconductor package includes a lower redistribution structure including a lower redistribution layer, a lower chip structure disposed on the lower redistribution structure, a plurality of posts disposed around the lower chip structure and including a lower metal layer on the lower redistribution layer and an upper metal layer on the lower metal layer, an encapsulant covering respective side surfaces of the lower chip structure and the plurality of posts, a heat dissipation member disposed on the encapsulant and vertically overlapping at least a portion of the lower chip structure, an upper chip structure disposed on one side of the heat dissipation member and vertically overlapping at least a portion of the plurality of posts, and electrically connected to the lower redistribution layer through the plurality of posts, and external connection bumps disposed below the lower redistribution structure. The lower metal layer and the upper metal layer include different metals.

### CROSS-REFERENCE TO RELATED APPLICATION(S)

This application claims priority under 35 U.S.C. 119 to Korean Patent Application No. 10-2023-0034304, filed on Mar. 16, 2023 in the Korean Intellectual Property Office, the disclosure of which is incorporated by reference herein in its entirety.

### TECHNICAL FIELD

Embodiments of the present inventive concept relate to a semiconductor package.

### DISCUSSION OF RELATED ART

As electronic devices become smaller, lighter and faster, the use of miniaturized and high-performance semiconductor chips is increasing. Effective heat dissipation characteristics may increase the reliability of such high-performance semiconductor chips.

### SUMMARY

Example embodiments provide a semiconductor package having increased reliability.

According to example embodiments, a semiconductor package includes a lower redistribution structure including a lower redistribution layer, a lower chip structure disposed on the lower redistribution structure and electrically connected to the lower redistribution layer, a plurality of posts disposed adjacent to the lower chip structure and including a lower metal layer disposed on the lower redistribution layer and an upper metal layer disposed on the lower metal layer, an encapsulant covering respective side surfaces of the lower chip structure and the plurality of posts, a heat dissipation member disposed on the encapsulant and vertically overlapping at least a portion of the lower chip structure, an upper chip structure disposed on one side of the heat dissipation member and vertically overlapping at least a portion of the plurality of posts, and electrically connected to the lower redistribution layer through the plurality of posts, and a plurality of external connection bumps disposed below the lower redistribution structure and electrically connected to the lower redistribution layer. The lower metal layer and the upper metal layer include different metals.

According to example embodiments, a semiconductor package includes a lower redistribution structure, a lower chip structure disposed on the lower redistribution structure, a plurality of posts disposed adjacent to the lower chip structure and including a lower metal layer and an upper metal layer disposed on the lower metal layer, an encapsulant covering at least portions of the lower chip structure and the plurality of posts, a heat dissipation member disposed on the encapsulant and vertically overlapping at least a portion of the lower chip structure, an upper chip structure disposed on one side of the heat dissipation member and vertically overlapping at least portions of the plurality of posts, and a plurality of upper connection bumps disposed between the upper chip structure and the plurality of posts. A side surface of the lower metal layer and a side surface of the upper metal layer are in contact with the encapsulant, and an upper surface of the upper metal layer is in contact with the upper connection bumps.

According to example embodiments, a semiconductor package includes a lower redistribution structure, a lower chip structure disposed on the lower redistribution structure, a plurality of posts disposed adjacent to the lower chip structure and including a lower metal layer and an upper metal layer disposed on the lower metal layer, an encapsulant covering at least portions of the lower chip structure and the plurality of posts, a heat dissipation member disposed on the encapsulant and vertically overlapping at least a portion of the lower chip structure, and an upper chip structure disposed on one side of the heat dissipation member and vertically overlapping at least portions of the plurality of posts. A width of the lower metal layer is substantially equal to a width of the upper metal layer.

### BRIEF DESCRIPTION OF DRAWINGS

The above and other features of the present inventive concept will become more apparent by describing in detail embodiments thereof with reference to the accompanying drawings, in which:

FIG. 1A is a cross-sectional view of a semiconductor package according to an example embodiment;

FIG. 1B is a plan view of the semiconductor package of FIG. 1A;

FIG. 1C is a partially enlarged view of region ‘A’ of FIG. 1A;

FIGS. 2A and 2B are plan views illustrating an example modification of a heat dissipation member of FIG. 1B;

FIGS. 3A and 3B are cross-sectional views illustrating an example embodiment of a lower chip structure applicable to the semiconductor package of FIG. 1A;

FIG. 3C is a cross-sectional view illustrating an example embodiment of an upper chip structure applicable to the semiconductor package of FIG. 1A;

FIG. 4A is a cross-sectional view illustrating a semiconductor package according to an example embodiment;

FIG. 4B is a plan view illustrating the semiconductor package of FIG. 4A;

FIG. 5A is a cross-sectional view illustrating a semiconductor package according to an example embodiment;

FIG. 5B is a plan view illustrating the semiconductor package of FIG. 5A;

FIG. 6 is a cross-sectional view illustrating a semiconductor package according to an example embodiment;

FIG. 7A is a cross-sectional view illustrating a semiconductor package according to an example embodiment;

FIG. 7B is a plan view illustrating the semiconductor package of FIG. 7A; and

FIGS. 8A to 8F are cross-sectional views schematically illustrating a process of manufacturing a semiconductor package according to an example embodiment.

### DETAILED DESCRIPTION

Embodiments of the inventive concept will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below.

It will be understood that when a component such as a film, a region, a layer, etc., is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to exemplary embodiments, the parameter may be exactly the certain value or approximately the certain value within a measurement error as would be understood by a person having ordinary skill in the art. Other uses of these terms and similar terms to describe the relationships between components should be interpreted in a like fashion. For example, when elements are described as being substantially coplanar with one another, it is to be understood that elements are exactly coplanar with one another, or almost coplanar with one another (e.g., within a measurement error), as would be understood by a person having ordinary skill in the art.

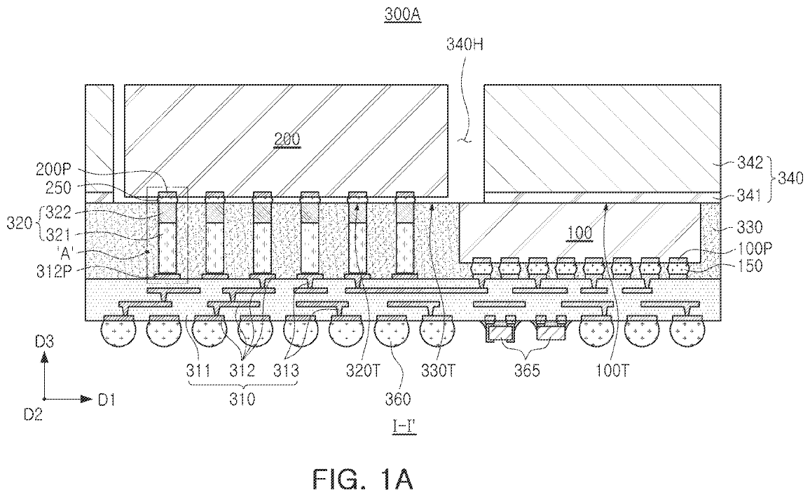

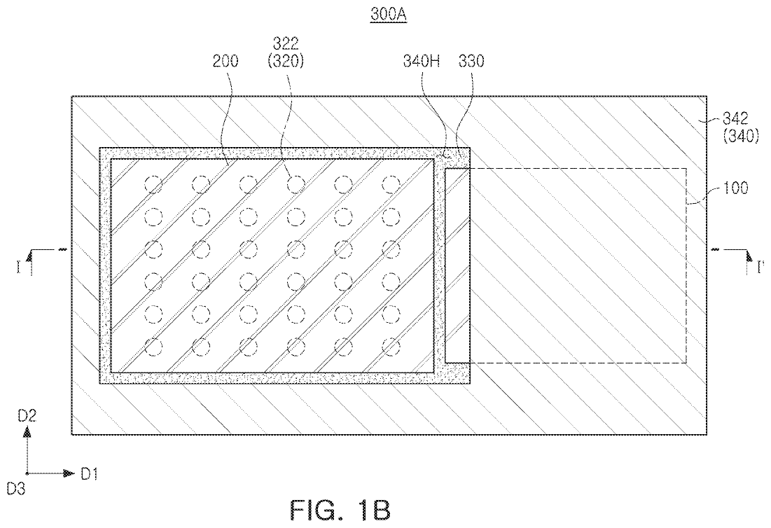

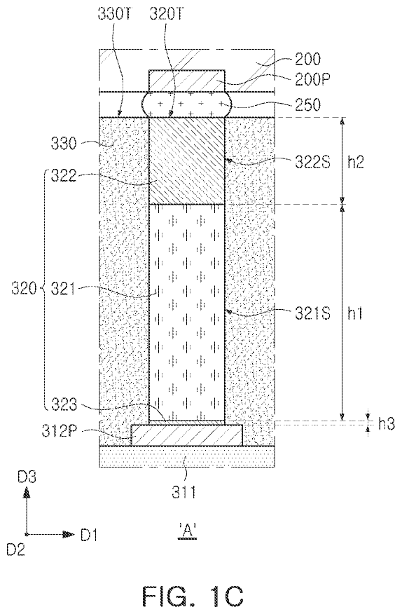

FIG. 1A is a cross-sectional view illustrating a semiconductor package 300A according to an example embodiment. FIG. 1B is a plan view illustrating the semiconductor package 300A of FIG. 1A. FIG. 1C is a partially enlarged view illustrating region ‘A’ of FIG. 1A.

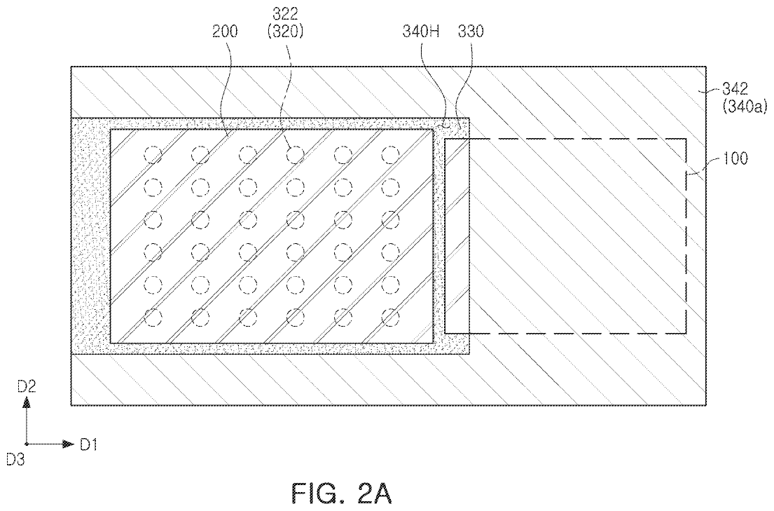

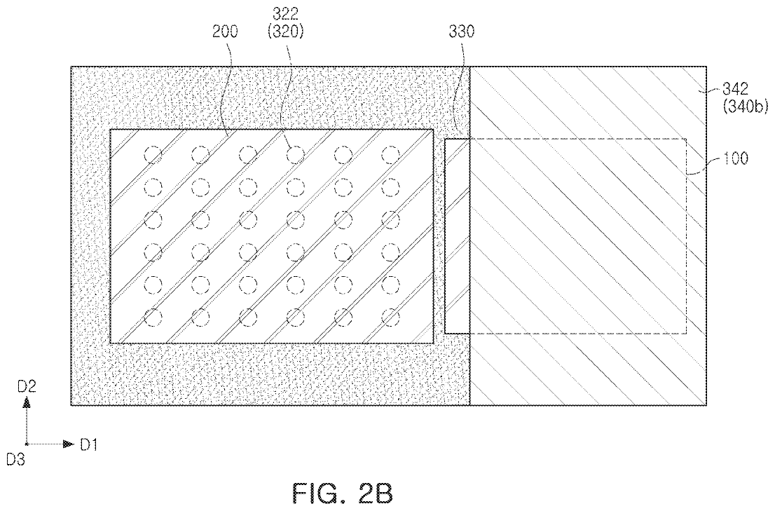

FIGS. 2A and 2B are plan views illustrating an example modification of a heat dissipation member of FIG. 1B.

Referring to FIGS. 1A to 1C, a semiconductor package 300A according to an example embodiment includes a lower chip structure 100, an upper chip structure 200, a lower redistribution structure 310, a plurality of posts 320, an encapsulant 330, and a heat dissipation member 340.

The lower chip structure 100 may include first connection terminals 100P disposed on the lower redistribution structure 310 and electrically connected to a lower redistribution layer 312. The first connection terminals 100P of the lower chip structure 100 may be connected to the lower redistribution layer 312 through lower connection bumps 150 disposed between the lower chip structure 100 and the lower redistribution structure 310.

The upper chip structure 200 is disposed on the lower redistribution structure 310 and may be located at a higher level than the lower chip structure 100. The upper chip structure 200 may be electrically connected to the lower redistribution layer 312 through the plurality of posts 320. The upper chip structure 200 may include second connection terminals 200P electrically connected to the plurality of posts 320. The second connection terminals 200P may be connected to the plurality of posts 320 through upper connection bumps 250 disposed between the upper chip structure 200 and the plurality of posts 320. The upper chip structure 200 may be electrically connected to the lower chip structure 100 through the lower redistribution layer 312 and the plurality of posts 320. An insulating material layer surrounding the upper connection bumps 250 may be formed below the upper chip structure 200.

The upper chip structure 200 may vertically overlap at least a portion of the plurality of posts 320. In addition, the upper chip structure 200 may be staggered with the lower chip structure 100 in the horizontal direction (e.g., D1) to expose at least a portion of the lower chip structure 100 in the vertical direction (e.g., D3). The upper chip structure 200 may be disposed on one side of the heat dissipation member 340 disposed on the lower chip structure 100. Since the upper chip structure 200 is not overlapped with a portion of the lower chip structure 100, the lower chip structure 100 may directly contact the heat dissipation member 340.

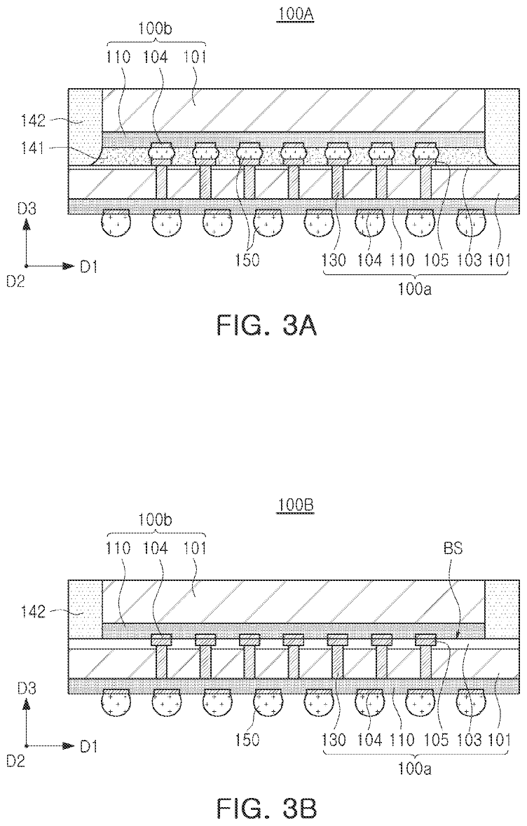

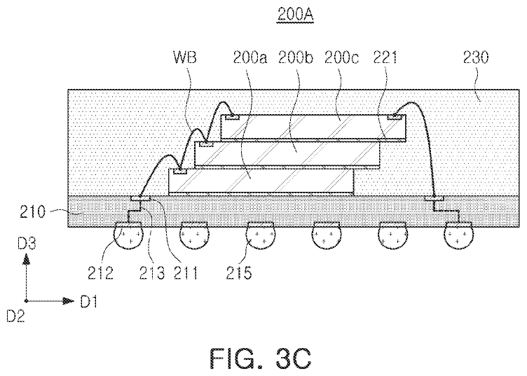

The lower chip structure 100 and the upper chip structure 200 may include a Semiconductor Wafer Integrated Circuit (IC) and a semiconductor wafer formed of a semiconductor element such as silicon and germanium or a compound semiconductor such as, for example, silicon carbide (SiC), gallium arsenide (GaAs), indium arsenide (InAs), and indium phosphide (InP). The lower chip structure 100 and the upper chip structure 200 may be semiconductor chips in a bare state on which separate bumps or wiring layers are not formed. However, the lower chip structure 100 and the upper chip structure 200 are not limited thereto, and may be packaged type semiconductor chips according to embodiments. The integrated circuits are logic circuits (or logic chips) such as, for example, central processors (CPUs), graphics processors (GPUs), field programmable gate arrays (FPGAs), application processors (APs), digital signal processors, cryptographic processors, microprocessors, microcontrollers, analog-to-digital converters, and application-specific ICs (ASICs), but may also be a memory circuit (or memory chip) including a volatile memory such as, for example, dynamic RAM (DRAM), static RAM (SRAM), and the like, and a non-volatile memory, such as, for example, a phase change RAM (PRAM), a magnetic RAM (MRAM), a resistive RAM (RRAM), and a flash memory. The lower chip structure 100 and the upper chip structure 200 may include different types of integrated circuits. For example, the lower chip structure 100 may include a logic circuit, and the upper chip structure 200 may include a memory circuit. Depending on example embodiments, the lower chip structure 100 and the upper chip structure 200 may respectively be a semiconductor package structure including a plurality of semiconductor chips, which will be described below with reference to FIGS. 3A to 3C.

The lower redistribution structure 310 is a support substrate on which the lower chip structure 100 is mounted, and may include a lower insulating layer 311, lower redistribution layers 312, and lower redistribution vias 313.

The lower insulating layer 311 may include an insulating resin. The insulating resin may include a thermosetting resin such as epoxy resins, a thermoplastic resin such as polyimide, or a resin impregnated with inorganic fillers in these resins, for example, prepreg, Ajinomoto Build-up Film (ABF), or Bismaleimide-Triazine (FR-4, BT). For example, the lower insulating layer 311 may include a photosensitive resin such as Photo-Imageable Dielectric (PID). The lower insulating layer 311 may include a plurality of insulating layers stacked in a vertical direction (Z-axis direction). Depending on the process, the boundary between the plurality of insulating layers may be unclear.

The lower redistribution layer 312 is disposed on or within the lower insulating layer 311 and may redistribute the first connection terminal 100P of the lower chip structure 100. The lower redistribution layer 312 may include a metal containing, for example, copper (Cu), aluminum (Al), silver (Ag), tin (Sn), gold (Au), nickel (Ni), lead (Pb), titanium (Ti), or alloys thereof. The lower redistribution layer 312 may perform various functions according to design. For example, the lower redistribution layer 312 may include a ground (GND) pattern, a power (PWR) pattern, and a signal (Signal: S) pattern. In this case, the signal (S) pattern may be defined as a transmission path of various signals, for example, data signals, excluding the ground (GND) pattern and the power (PWR) pattern. The lower redistribution layer 312 may include more or fewer redistribution layers than illustrated in the figures. The lower redistribution layer 312 may include redistribution pads 312P disposed on the upper surface of the lower redistribution structure 310. The redistribution pads 312P may be electrically connected to the plurality of posts 320 and the first connection terminals 100P of the lower chip structure 100.

The lower redistribution via 313 may extend vertically within the lower insulating layer 311 and be electrically connected to the lower redistribution layer 312. For example, the lower redistribution vias 313 may interconnect lower redistribution layers 312 of different levels. The lower redistribution via 313 may include a signal via, a ground via, and a power via. The lower redistribution via 313 may include a metal material including, for example, copper (Cu), aluminum (Al), silver (Ag), tin (Sn), gold (Au), nickel (Ni), lead (Pb), titanium (Ti), or alloys thereof. The lower redistribution via 313 may be a filled via in which a metal material is filled in the via hole or a conformal via in which a metal material extends along an inner wall of the via hole.

External connection bumps 360 may be disposed below the lower redistribution structure 310. The external connection bumps 360 may be electrically connected to the lower redistribution layer 312. The semiconductor package 300A may be connected to external devices such as a module substrate and a system board through the external connection bumps 360. The external connection bumps 360 may have a shape in which a pillar (or under bump metal) and a ball are combined. The pillar may contain copper (Cu) or an alloy of copper (Cu), and the ball may contain a low melting point metal, for example, tin (Sn) or an alloy containing tin (Sn) (Sn—Ag—Cu). Depending on example embodiments, the external connection bumps 360 may include only pillars or balls. Depending on the example embodiment, a resist layer may be formed on the lower surface of the lower redistribution structure 310, which may protect the external connection bumps 360 from physical and chemical damage.

In addition, at least one passive element 365 may be disposed below the lower redistribution structure 310. The passive element 365 may include, for example, a capacitor, an inductor, or beads. The passive element 365 may be flip-chip bonded to the lower surface of the lower redistribution structure 310. The passive elements 365 may be electrically connected to the lower redistribution layer 312 through solder bumps or the like. An underfill resin may be filled between the passive element 365 and the lower redistribution structure 310.

The plurality of posts 320 may be disposed adjacent to (e.g., around) the lower chip structure 100 and penetrate through the encapsulant 330, and may electrically connect the lower redistribution layer 312 and the upper chip structure 200. The plurality of posts 320 may extend in a vertical direction (e.g., D3) within the encapsulant 330. Upper surfaces 320T of the plurality of posts 320 may be exposed from the encapsulant 330 and connected to the second connection terminals 200P of the upper chip structure 200 through the upper connection bumps 250. The plurality of posts 320 may have a cylindrical shape, but is not limited thereto.

The plurality of posts 320 may include, for example, copper (Cu), nickel (Ni), titanium (Ti), lead (Pb), aluminum (Al), silver (Ag), gold (Au), platinum (Pt) or alloys thereof. In example embodiments of the present inventive concept, by forming the lower and upper portions of the plurality of posts 320 with different types of metal, contamination of the lower chip structure 100 by metal (e.g., copper (Cu)) residues generated during the planarization process of the encapsulant 330 may be prevented or reduced, and reliability may be increased. The plurality of posts 320 may include a lower metal layer 321 disposed on the lower redistribution layer 312 and an upper metal layer 322 disposed on the lower metal layer 321. The lower metal layer 321 and the upper metal layer 322 may include different metals. The upper metal layer 322 may include a second metal having a diffusion coefficient less than a diffusion coefficient of the first metal (or metal atom) included in the lower metal layer 321. For example, the upper metal layer 322 may include a metal having a diffusion coefficient less than a diffusion coefficient of the metal included in the lower metal layer 321 in silicon.

In an example embodiment, the lower metal layer 321 may include copper (Cu), and the upper metal layer 322 may include at least one of nickel (Ni), gold (Au), chromium (Cr), and molybdenum (Mo). For example, the lower metal layer 321 may be formed by plating copper (Cu), and the upper metal layer 322 may be formed by plating nickel (Ni). The upper metal layer 322 is formed to have a thickness or height that is not completely removed during the planarization process of the encapsulant 330, which may prevent the lower metal layer 321 from being partially removed or exposed by the planarization process. Accordingly, the upper metal layer 322 may prevent or reduce contamination of the lower chip structure 100 by copper (Cu) residues, for example, contamination of silicon (Si) constituting the lower chip structure 100. A first height h1 of the lower metal layer 321 may be about equal to or greater than a second height h2 of the upper metal layer 322.

The plurality of posts 320 may further include a seed layer 323 disposed between the lower metal layer 321 and the lower redistribution layer 312 (or the redistribution pad 312P). The second height h2 of the upper metal layer 322 may be greater than a third height h3 of the seed layer 323. The seed layer 323 may include, for example, titanium (Ti), copper (Cu), or the like.

The second height h2 of the upper metal layer 322 may be greater than or equal to about 3 μm, for example, within the range of about 3 μm to about 100 μm, about 3 μm to about 80 μm, about 3 μm to about 60 μm, about 3 μm to about 40 μm, about 3 μm to about 20 μm, about 3 μm to about 10 μm, or the like, but is not limited thereto.

The upper surface 320T of the upper metal layer 322 (or the upper surface of the post 320) may be substantially coplanar with an upper surface 330T of the encapsulant 330. Depending on example embodiments, the upper surface 320T of the upper metal layer 322 may be substantially coplanar with the upper surface 330T of the encapsulant 330 and the upper surface 100T of the lower chip structure 100. The upper surface 320T of the upper metal layer 322 exposed from the encapsulant 330 may directly contact the upper connection bumps 250.

Since the lower metal layer 321 and the upper metal layer 322 are sequentially formed in the hole of the resist layer by an electroplating process using the seed layer 323, the width of the lower metal layer 321 may be substantially equal to the width of the upper metal layer 322. A side surface 321S of the lower metal layer 321 and a side surface 322S of the upper metal layer 322 may define the same flat surface. In addition, the entirety of the side surface 321S of the lower metal layer 321 and the side surface 322S of the upper metal layer 322 may be in contact with the encapsulant 330.

The encapsulant 330 may cover at least a portion of each of the lower chip structure 100 and the plurality of posts 320. The encapsulant 330 may cover respective side surfaces of the lower chip structure 100 and each of the plurality of posts 320. The encapsulant 330 may expose an upper surface 320T of each of the plurality of posts 320. Depending on the example embodiment, the encapsulant 330 may expose the upper surface 100T of the lower chip structure 100. The upper surface 330T of the encapsulant 330 may be substantially coplanar with the upper surface 100T of the lower chip structure 100 and the upper surface 320T of the plurality of posts 320. The encapsulant 330 may include, for example, a thermosetting resin such as epoxy resin, a thermoplastic resin such as polyimide, or prepreg, ABF, FR-4, BT, or Epoxy Molding Compound (EMC). For example, the encapsulant 330 may include EMC.

The heat dissipation member 340 may be disposed on the encapsulant 330 and may overlap at least a portion of the lower chip structure 100 in the vertical direction (e.g., D3). The heat dissipation member 340 may be disposed on one side of the upper chip structure 200. A horizontal width (e.g., a width in the direction D1) of a portion of the heat dissipation member 340 overlapping the lower chip structure 100 may be less than a horizontal width (e.g., a width in the direction D1) of the upper chip structure 200. The heat dissipation member 340 may control warpage of the semiconductor package 300A and dissipate heat generated from the lower chip structure 100 externally. The heat dissipation member 340 may include a thermal interface material (TIM) 341 and a heat slug 342. The thermal interface material 341 may contact the upper surface 100T of the lower chip structure 100. The thermal interface material 341 may include, for example, thermally conductive adhesive tape, thermally conductive grease, thermally conductive adhesive, or the like. The heat slug 342 may be disposed on the thermal interface material 341. The heat slug 342 may include a material with excellent thermal conductivity such as, for example, aluminum (Al), gold (Au), silver (Ag), copper (Cu), iron (Fe), graphite, graphene, etc. Depending on the example embodiment, the heat dissipation member 340 may have a cavity 340H in which the upper chip structure 200 is accommodated. For example, as illustrated in FIG. 1B, the cavity 340H may be a region penetrating the plate-shaped heat dissipation member 340. In this case, the heat dissipation member 340 may surround four surfaces of the upper chip structure 200. Depending on the example embodiment, an insulating resin may be filled between the heat dissipation member 340 and the upper chip structure 200. Hereinafter, a planar shape of a heat dissipation member according to an example modification will be described with reference to FIGS. 2A and 2B.

Referring to FIG. 2A, a heat dissipation member 340a of an example modification may be formed to surround at least three surfaces of the upper chip structure 200 on a plane. In this case, the cavity 340H may have a ‘U’ shape with one side open.

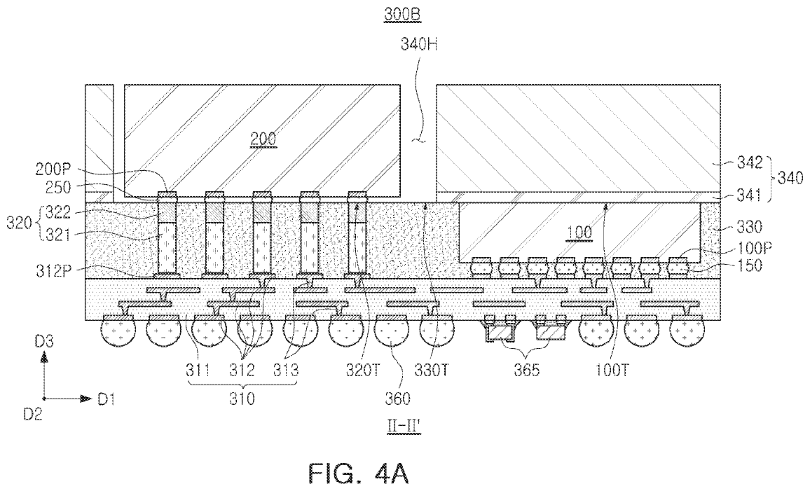

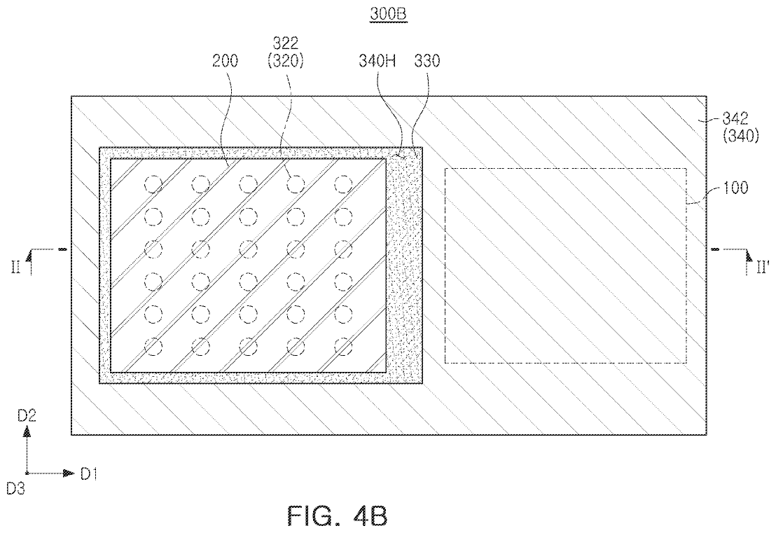

Referring to FIG. 2B, a heat dissipation member 340b of an example modification may be formed on only one side of the upper chip structure 200 on a plane. In this case, in an embodiment, the heat dissipation member 340b does not have a cavity surrounding the upper chip structure 200. Depending on the example embodiment, the heat dissipation member 340b may cover a boundary between a side surface of the lower chip structure 100 adjacent to the upper chip structure 200 and the encapsulant 330 (see FIGS. 4A and 4B).

FIGS. 3A and 3B are cross-sectional views illustrating an example embodiment of a lower chip structure applicable to the semiconductor package 300A of FIG. 1A. FIG. 3C is a cross-sectional view illustrating an example embodiment of an upper chip structure applicable to the semiconductor package 300A of FIG. 1A.

Referring to FIG. 3A, a lower chip structure 100A according to an example embodiment may include a plurality of semiconductor chips 100a and 100b stacked vertically (e.g., in the D3 direction). At least a portion (e.g., 100a) of the plurality of semiconductor chips 100a and 100b may include through-vias 130 electrically connecting the plurality of semiconductor chips 100a and 100b to each other. The plurality of semiconductor chips 100a and 100b may be chiplets constituting a multi-chip module (MCM). The plurality of semiconductor chips 100a and 100b may include, for example, a central processing unit (CPU), graphics processing unit (GPU), field programmable gate array (FPGA), digital signal processor (DSP), cryptographic processor, microprocessor, microcontroller, analog-to-digital converter, application specific integrated circuit (ASIC), volatile memory, non-volatile memory, input/output (I/O) circuit, analog circuit, serial-parallel conversion circuit, etc.

The lower chip structure 100A may include a first semiconductor chip 100a and a second semiconductor chip 100b. The first semiconductor chip 100a may include a processor circuit, and the second semiconductor chip 100b may include at least one of input/output circuits, analog circuits, memory circuits, and serial-to-parallel conversion circuits for processor circuits. The plurality of semiconductor chips 100a and 100b may be provided in greater numbers than illustrated in the figures. According to an example embodiment, the lower chip structure 100A may further include a molding member 142 covering at least a portion of each of the first semiconductor chip 100a and the second semiconductor chip 100b. Depending on the example embodiment, an underfill part 141 may be formed between the first semiconductor chip 100a and the second semiconductor chip 100b.

Each of the first semiconductor chip 100a and the second semiconductor chip 100b may include a substrate 101, a lower pad 104, and/or a circuit layer 110. The second semiconductor chip 100b may further include an upper protective layer 103, an upper pad 105, and/or a through-via 130. The substrate 101 may include, for example, a semiconductor element such as silicon or germanium (Ge), or a compound semiconductor such as silicon carbide (SiC), gallium arsenide (GaAs), indium arsenide (InAs), or indium phosphide (InP). The substrate 101 may have a silicon on insulator (SOI) structure. The substrate 101 may have a conductive region, for example, a well doped with impurities, or an active surface doped with impurities and an inactive surface doped with impurities. The substrate 101 may include various device isolation structures such as a shallow trench isolation (STI) structure.

The upper protective layer 103 is formed on the inactive surface of the substrate 101 and may protect the substrate 101. The upper protective layer 103 may be formed of an insulating layer such as, for example, a silicon oxide layer, a silicon nitride layer, or a silicon oxynitride layer. However, the material of the upper protective layer 103 is not limited thereto. For example, the upper protective layer 103 may be formed of a polymer such as polyimide (PI). According to embodiments, a lower protective layer may be further formed on the lower surface of the circuit layer 110.

The upper pad 105 may be disposed on the upper protective layer 103. The upper pad 105 may include at least one of, for example, aluminum (Al), copper (Cu), nickel (Ni), tungsten (W), platinum (Pt), and gold (Au). The lower pad 104 may be disposed below the circuit layer 110 and may include a material similar to the material of the upper pad 105. However, the materials of the upper pad 105 and lower pad 104 are not limited thereto.

The circuit layer 110 is disposed on the active surface of the substrate 101 and may include various types of devices. For example, the circuit layer 110 may include a field effect transistor (FET) (e.g., a planar FET) or a FinFET, memory elements, such as, for example, a flash memory, a dynamic random access memory (DRAM), a static random access memory (SRAM), an electrically erasable programmable read-only memory (EEPROM), a phase-change random access memory (PRAM), a magnetoresistive random access memory (MRAM), a ferroelectric random access memory (FeRAM), a resistive random access memory (RRAM), and the like, logic elements such as, for example, AND, OR, and NOT logic elements, various active and/or passive components, such as, for example, system large scale integration (LSI), CMOS imaging sensor (CIS), micro-electro-mechanical system (MEMS), and the like. The circuit layer 110 may include a wiring structure electrically connected to the above-described elements and an interlayer insulating layer surrounding the wiring structure. The interlayer insulating layer may include, for example, silicon oxide or silicon nitride. The wiring structure may include, for example, multilayer wiring and/or vertical contacts. The wiring structure may connect elements of the circuit layer 110 to each other, connect elements to a conductive region of the substrate 101, or connect elements to the through-vias 130.

The through-via 130 may penetrate the substrate 101 in a vertical direction (e.g., D3) and provide an electrical path connecting the upper pad 105 and the lower pads 104. The through-via 130 may include a conductive plug and a barrier film surrounding the conductive plug. The conductive plug may include metal such as, for example, tungsten (W), titanium (Ti), aluminum (Al), or copper (Cu). The conductive plug may be formed through, for example, a plating process, a physical vapor deposition (PVD) process, or a (chemical vapor deposition) CVD process. The barrier film may include an insulating barrier film and/or a conductive barrier film. The insulating barrier film may be formed of, for example, an oxide film, a nitride film, a carbide film, a polymer, or combinations thereof. A conductive barrier film may be disposed between the insulating barrier film and the conductive plug. The conductive barrier film may include, for example, a metal compound such as tungsten nitride (WN), titanium nitride (TiN), or tantalum nitride (TaN). The barrier film may be formed by, for example, a PVD process or a CVD process.

Connection bumps 150 may be disposed below the first semiconductor chip 100a and between the first semiconductor chip 100a and the second semiconductor chip 100b. The connection bumps 150 may have a shape in which a pillar (or under bump metal) and a ball are combined. The pillar may contain copper (Cu) or an alloy of copper (Cu), and the ball may contain a low melting point metal such as, for example, tin (Sn) or an alloy containing tin (Sn) (Sn—Ag—Cu). Depending on the example embodiment, the connection bumps 150 may have a shape formed of only pillars or balls.

Referring to FIG. 3B, the lower chip structure 100B according to an example embodiment may include a plurality of semiconductor chips 100a and 100b that are directly bonded and coupled without a separate connecting member (e.g., a solder bump, a copper post, etc.). The lower chip structure 100B may include a bonding surface BS in which an upper surface of the first semiconductor chip 100a and a lower surface of the second semiconductor chip 100b are bonded to each other. The bonding surface BS may be formed of metal bonding and dielectric bonding. For example, the upper protective layer 103 of the first semiconductor chip 100a and the circuit layer 110 of the second semiconductor chip 100b forming the bonding surface BS may include substances that may be bonded to each other such as, for example, at least one of silicon oxide (SiO) silicon nitride (SiN), and silicon carbonitride (SiCN).

Referring to FIG. 3C, an upper chip structure 200A of an example embodiment may include a substrate 210, a plurality of semiconductor chips 200a, 200b, and 200c, and a molding member 230.

The substrate 210 is a support substrate on which the plurality of semiconductor chips 200a, 200b, and 200c are mounted, and may include, for example, a printed circuit board (PCB), a ceramic substrate, a glass substrate, a tape wiring board, and the like. The substrate 210 may include a lower pad 212 and an upper pad 211 electrically connected externally, on the lower and upper surfaces, respectively. In addition, the substrate 210 may include a wiring circuit 213 electrically connecting the lower pad 212 and the upper pad 211 to each other.

The plurality of semiconductor chips 200a, 200b, and 200c may be mounted on the substrate 210 by, for example, wire bonding or flip chip bonding. For example, the plurality of semiconductor chips 200a, 200b, and 200c are stacked vertically (e.g., in the direction D3) on the substrate 210, and may be electrically connected to the upper pad 211 of the substrate 210 by the bonding wire WB. The plurality of semiconductor chips 200a, 200b, and 200c may be attached to the substrate 210 and attached to each other by an adhesive film 221. The plurality of semiconductor chips 200a, 200b, and 200c may include volatile and/or nonvolatile memory chips.

The molding member 230 may cover at least a portion of the plurality of semiconductor chips 200a, 200b, and 200c on the substrate 210. The molding member 230 may include the same or similar material as the above-described encapsulant 330. Connection bumps 215 may be disposed below the substrate 210. The connection bumps 215 may be electrically connected to the plurality of semiconductor chips 200a, 200b, and 200c through the wiring circuit 213. The connection bumps 215 may include, for example, tin (Sn) or an alloy containing tin (Sn) (e.g., Sn—Ag—Cu).

The lower chip structures 100A and 100B and the upper chip structure 200A described above with reference to FIGS. 3A to 3C represent example embodiments, and the shapes of the lower chip structure 100 and the upper chip structure 200 applicable to the semiconductor package according to an example embodiment are not limited thereto.

FIG. 4A is a cross-sectional view illustrating a semiconductor package 300B according to an example embodiment. FIG. 4B is a plan view illustrating the semiconductor package 300B of FIG. 4A.

Referring to FIGS. 4A and 4B, the semiconductor package 300B of an example embodiment may have the same or similar features as those described with reference to FIGS. 1A to 3C, except that the heat dissipation member 340 overlaps the entire lower chip structure 100. The heat dissipation member 340 may cover an interface between one side surface of the lower chip structure 100 disposed adjacent to the plurality of posts 320 and the encapsulant 330. On a plane, the heat dissipation member 340 has a plane area larger than a plane area of the lower chip structure 100 and may completely overlap the lower chip structure 100. Accordingly, warpage characteristics of the semiconductor package 300B as well as heat dissipation characteristics of the lower chip structure 100 may be improved.

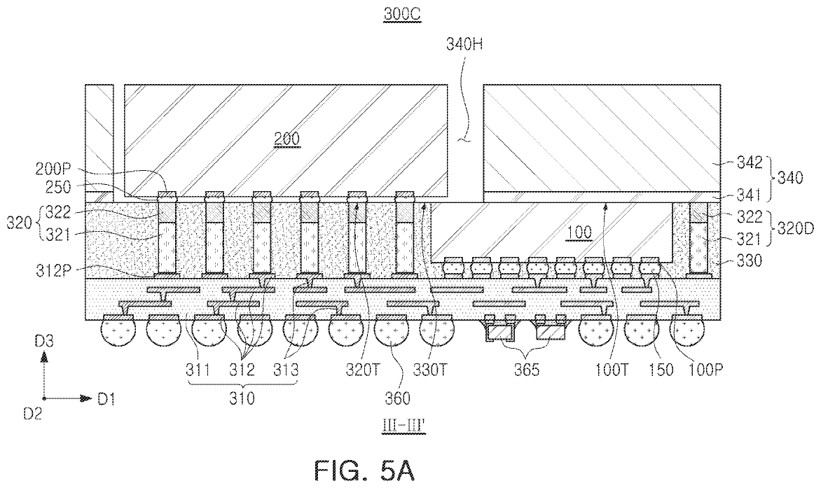

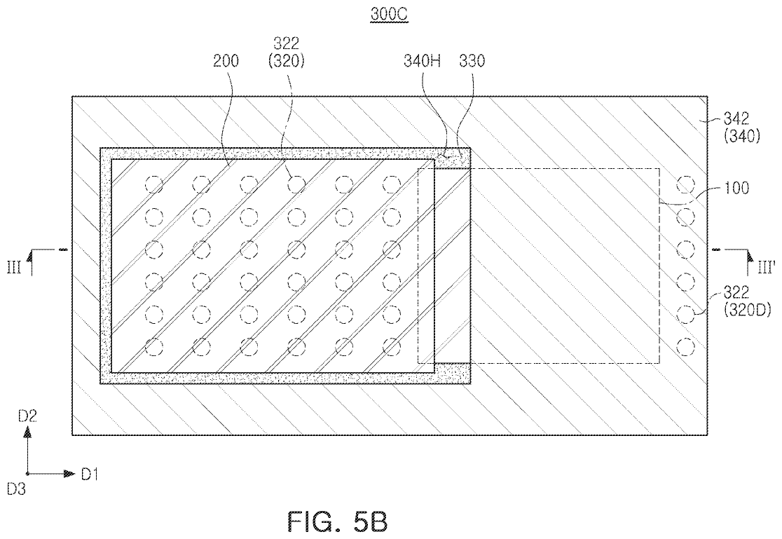

FIG. 5A is a cross-sectional view illustrating a semiconductor package 300C according to an example embodiment. FIG. 5B is a plan view illustrating the semiconductor package 300C of FIG. 5A.

Referring to FIGS. 5A and 5B, the semiconductor package 300C according to an example embodiment may have the same or similar features as those described with reference to FIGS. 1A to 4B, except for including at least one dummy post 320 electrically insulated from the upper chip structure 200. The plurality of posts 320 may include dummy posts 320D that do not overlap the upper chip structure 200 vertically (e.g., in the direction D3). The dummy posts 320D may include a lower metal layer 321 and an upper metal layer 322. The lower metal layer 321 and the upper metal layer 322 may include different metals. For example, the lower metal layer 321 may include copper (Cu), and the upper metal layer 322 may include at least one of nickel (Ni), titanium (Ti), lead (Pb), aluminum (Al), silver (Ag), gold (Au), and platinum (Pt). As illustrated in FIG. 5B, the dummy posts 320D may be disposed on overlapping positions with the heat dissipation member 340. Depending on the example embodiment, the dummy posts 320D may contact the lower redistribution layer 312 and the heat dissipation member 340.

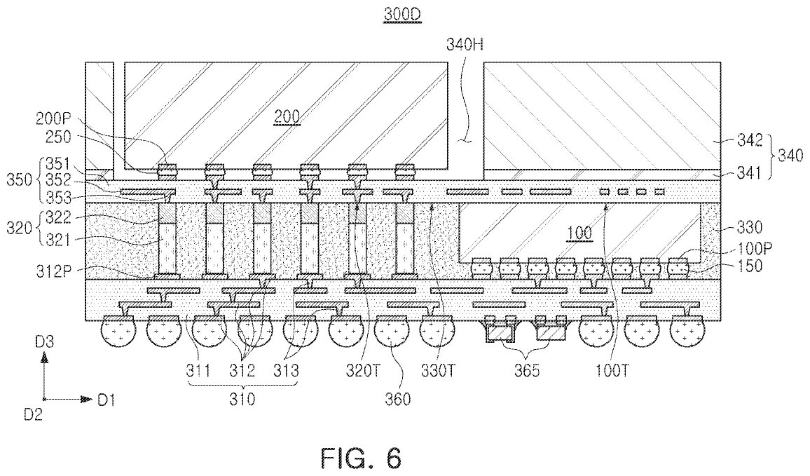

FIG. 6 is a cross-sectional view illustrating a semiconductor package 300D according to an example embodiment.

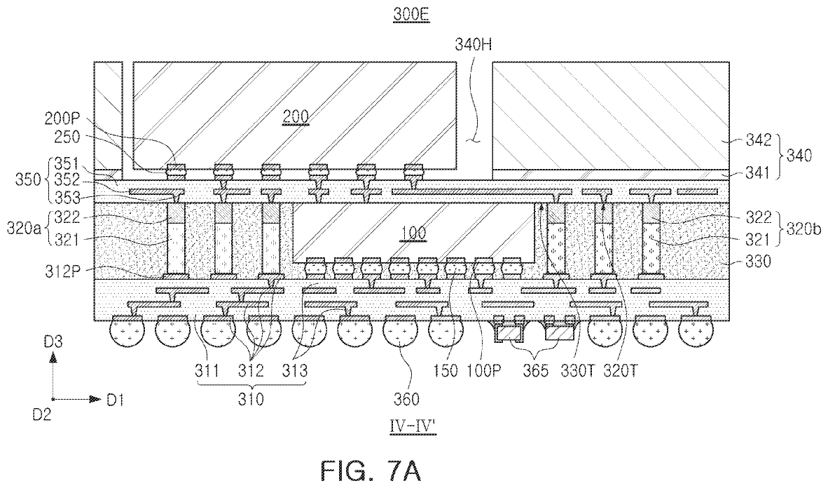

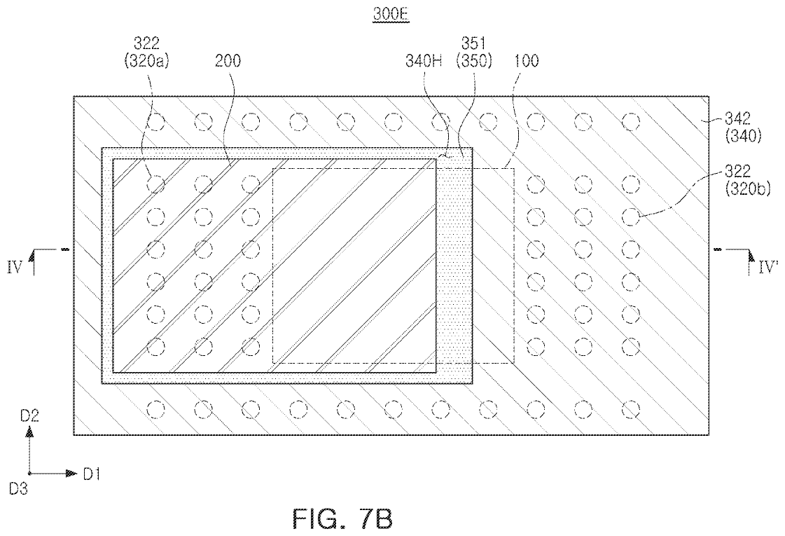

Referring to FIG. 6, the semiconductor package 300D of an example embodiment may have the same or similar features as those described with reference to FIGS. 1A to 5B except for further including an upper redistribution structure 350 disposed on the plurality of posts 320. The upper redistribution structure 350 is disposed below the heat dissipation member 340 and the upper chip structure 200, and may include an upper insulating layer 351, upper redistribution layers 352, and upper redistribution vias 353. The upper redistribution structure 350 may connect posts 320 in positions that do not overlap the upper chip structure 200 to the upper chip structure 200 (refer to FIGS. 7A and 7B).

The upper insulating layer 351 may be disposed on the upper surface 330T of the encapsulant 330. The upper insulating layer 351 may include a thermosetting resin such as epoxy resins, a thermoplastic resin such as polyimide, or a resin impregnated with inorganic fillers in these resins such as, for example, prepreg, AJINOMOTO BUILD-UP FILM (ABF), FR-4, or bismaleimide-triazine (BT). For example, the upper insulating layer 351 may include a photosensitive resin such as PID. The upper insulating layer 351 may include a plurality of insulating layers stacked in a vertical direction (e.g., in the direction D3). Depending on the process, the boundary between the plurality of insulating layers may be unclear.

The upper redistribution layer 352 is disposed on or within the upper insulating layer 351 and may redistribute the second connection terminal 200P of the upper chip structure 200. The upper redistribution layer 352 may include a metal including, for example, copper (Cu), aluminum (Al), silver (Ag), tin (Sn), gold (Au), nickel (Ni), lead (Pb), or titanium (Ti), or alloys thereof. The upper redistribution layer 352 may perform various functions according to design. For example, the upper redistribution layer 352 may include a ground (GND) pattern, a power (PoWeR: PWR) pattern, and a signal (S) pattern. The upper redistribution layer 352 may include more or fewer redistribution layers than illustrated in the figures.

The upper redistribution via 353 may vertically extend within the upper insulating layer 351 and be electrically connected to the upper redistribution layer 352. For example, the upper redistribution vias 353 may interconnect upper redistribution layers 352 of different levels. The upper redistribution via 353 may include a metallic material containing, for example, copper (Cu), aluminum (Al), silver (Ag), tin (Sn), gold (Au), nickel (Ni), lead (Pb), titanium (Ti), or alloys thereof. The upper redistribution via 353 may be a filled via in which a metal material is filled in the via hole or a conformal via in which a metal material extends along an inner wall of the via hole.

FIG. 7A is a cross-sectional view illustrating a semiconductor package 300E according to an example embodiment. FIG. 7B is a plan view illustrating the semiconductor package 300E of FIG. 7A.

Referring to FIGS. 7A and 7B, the semiconductor package 300E according to an example embodiment may have the same or similar features as those described with reference to FIGS. 1A to 6, except that some of the posts 320 of the plurality of posts 320 electrically connected to the upper chip structure 200 do not overlap the upper chip structure 200. The plurality of posts 320 may include first posts 320a overlapping the upper chip structure 200 and second posts 320b not overlapping the upper chip structure 200. The second posts 320b may overlap the heat dissipation member 340 in a vertical direction (e.g., the D3 direction). At least a portion of the second posts 230b may be electrically connected to the upper chip structure 200 through the upper redistribution layer 352. Depending on example embodiments, the area of the overlapping region between the lower chip structure 100 and the upper chip structure 200 may be greater than the area of the overlapping region between the lower chip structure 100 and the heat dissipation member 340. However, the inventive concept is not limited thereto. The first posts 320a and the second posts 320b may include a lower metal layer 321 and an upper metal layer 322. The lower metal layer 321 and the upper metal layer 322 may include different metals. For example, the lower metal layer 321 may include copper (Cu), and the upper metal layer 322 may include at least one of nickel (Ni), titanium (Ti), lead (Pb), aluminum (Al), silver (Ag), gold (Au), and platinum (Pt).

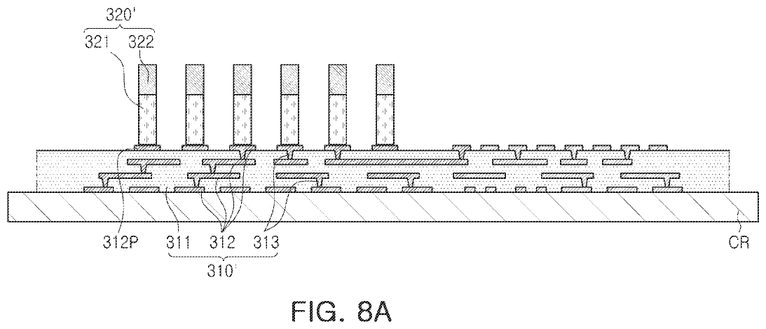

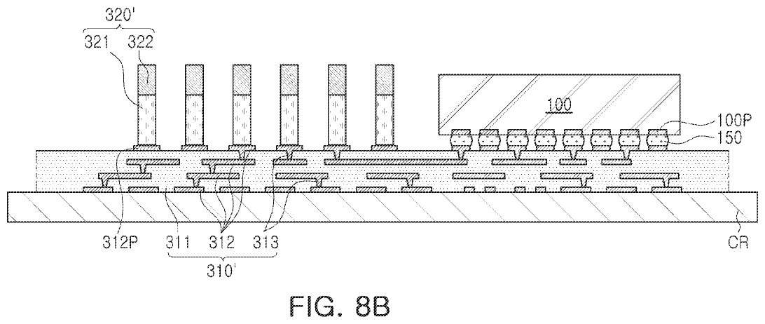

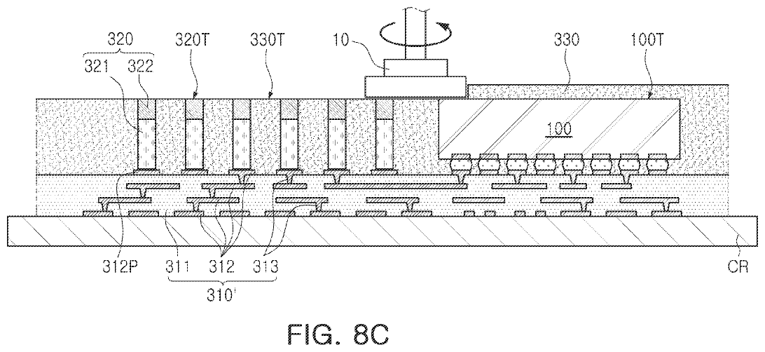

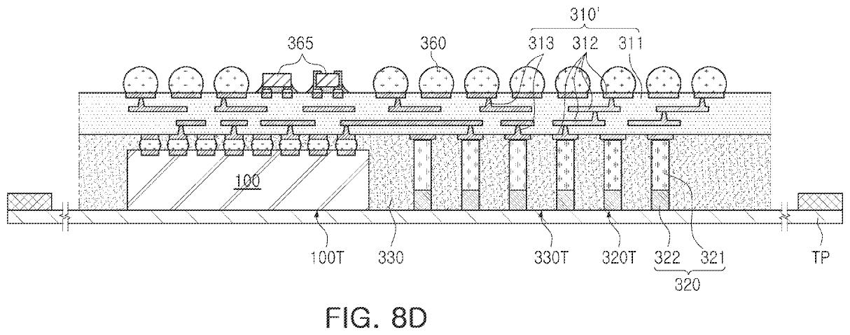

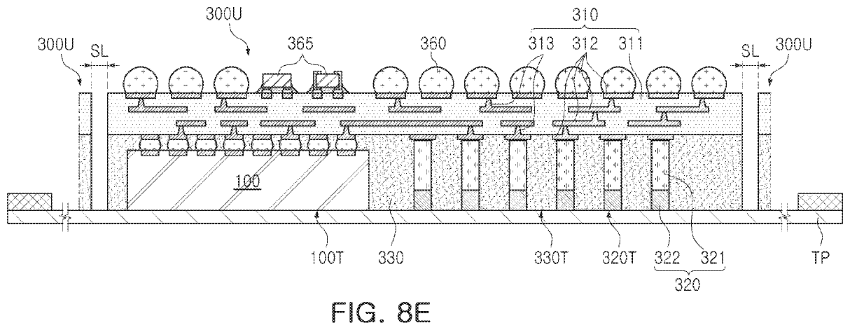

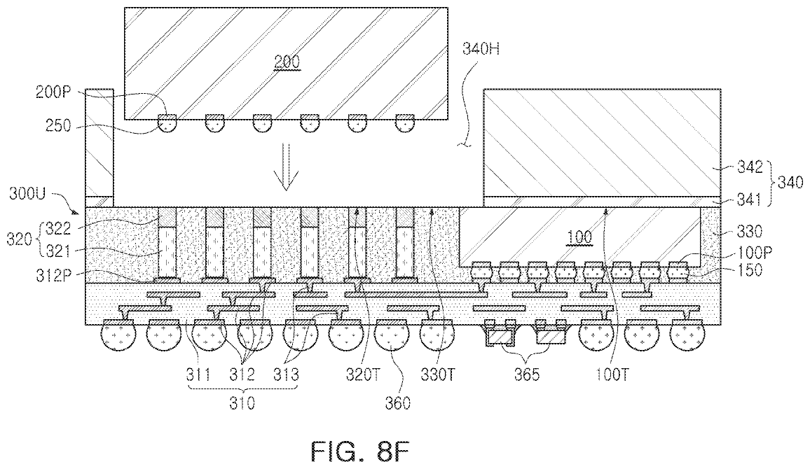

FIGS. 8A to 8F are cross-sectional views schematically illustrating a manufacturing process of a semiconductor package according to an example embodiment.

Referring to FIG. 8A, a preliminary lower redistribution structure 310′ and preliminary posts 320′ may be formed on a carrier substrate CR.

The carrier substrate CR may be sequentially coated with a polymer layer including a curable resin on a copper clad laminate (CCL), and a metal layer including, for example, nickel (Ni), titanium (Ti), and the like.

The preliminary lower redistribution structure 310′ may be formed at a wafer level or a panel level comprised of a plurality of lower redistribution structures. The preliminary lower redistribution structure 310′ may include a lower insulating layer 311, a lower redistribution layer 312, and lower redistribution vias 313. The lower insulating layer 311 may be formed by sequentially coating and curing a photosensitive material, for example, PID. The lower redistribution layer 312 and the lower redistribution vias 313 may be formed by performing an exposure process and a development process to form a via hole penetrating the lower insulating layer 311, and patterning a metal material on the lower insulating layer 311 using a plating process. A redistribution pad 312P may be formed on an upper surface of the preliminary lower redistribution structure 310′. A barrier film including, for example, nickel (Ni), gold (Au), or the like may be formed on the redistribution pad 312P.

The preliminary posts 320′ may be formed on the redistribution pad 312P. The preliminary posts 320′ may include a lower metal layer 321 and an upper metal layer 322. The lower metal layer 321 and the upper metal layer 322 may include different metals. In an example embodiment, the lower metal layer 321 may include copper (Cu), and the upper metal layer 322 may include nickel (Ni). The lower metal layer 321 may be formed by plating copper (Cu), and the upper metal layer 322 may be formed by plating nickel (Ni) on the lower metal layer 321.

The upper metal layer 322 is formed to have a thickness or height that is not completely removed during the planarization process of the encapsulant 330, thereby preventing partial removal or exposure of the lower metal layer 321 by the planarization process (see FIG. 8C). Accordingly, the upper metal layer 322 may prevent contamination of the lower chip structure 100 by copper (Cu) residues, for example, contamination of silicon (Si) constituting the lower chip structure 100.

Referring to FIG. 8B, the lower chip structure 100 may be mounted on the lower redistribution structure 310. The lower chip structure 100 may be mounted in a flip-chip method. For example, the lower chip structure 100 may be connected to the redistribution pad 312P through the lower connection bump 150 formed on the first connection terminal 100P. Depending on the example embodiment, an underfill may be formed between the lower chip structure 100 and the lower redistribution structure 310. The underfill may be formed using a capillary underfill (CUF) process, but is not limited thereto.

Referring to FIG. 8C, an encapsulant 330 sealing at least a portion of each of the lower chip structure 100 and the posts 320 may be formed. For example, the encapsulant 330 may be formed by applying and curing an epoxy molding compound (EMC). An upper portion of the encapsulant 330 may be flattened by polishing equipment 10. The planarization process may include, for example, a grinding process, a chemical mechanical polishing (CMP) process, and the like. Through the planarization process, the posts 320 from which the upper metal layer 322 of the preliminary posts 320′ is partially removed may be formed. The upper surface 320T of the posts 320 and the upper surface 100T of the lower chip structure 100 may be exposed through the upper surface 330T of the encapsulant 330. Accordingly, a flat surface composed of the upper surface 330T of the encapsulant 330, the upper surface 320T of the posts 320, and the upper surface 100T of the lower chip structure 100 may be formed.

Referring to FIG. 8D, external connection bumps 360 and passive elements 365 may be formed after attaching and inverting the preliminary lower redistribution structure 310′ to dicing tape TP. External connection bumps 360 may be attached to the lower redistribution layer 312. The passive elements 365 may be flip-chip mounted on the lower redistribution layer 312.

Referring to FIG. 8E, the plurality of package units 300 may be separated by cutting the preliminary lower redistribution structure 310′ along a sawing line SL. After that, a plurality of package units 300U may be turned over and subsequent processes may be performed.

Referring to FIG. 8F, a heat dissipation member 340 and an upper chip structure 200 may be disposed on an individual package unit 300U. The heat dissipation member 340 may be attached on the lower chip structure 100 by the thermal interface material 341. The heat dissipation member 340 may vertically overlap at least a portion of the lower chip structure 100. The upper chip structure 200 may be disposed in the cavity 340H of the heat dissipation member 340. The upper chip structure 200 may be connected to the plurality of posts 320 in a flip-chip manner. Depending on the example embodiment, an insulating material layer such as an underfill may be formed under the upper chip structure 200.

As set forth above, according to example embodiments, a semiconductor package having increased reliability may be provided by introducing posts composed of heterogeneous metal layers.

While the inventive concept has been particularly shown and described with reference to embodiments thereof, it will be understood by those of ordinary skill in the art that various changes in form and detail may be made therein without departing from the spirit and scope of the inventive concept as defined by the following claims.

What is claimed is:

1. A semiconductor package, comprising:
a lower redistribution structure comprising a lower redistribution layer;
a lower chip structure disposed on the lower redistribution structure and electrically connected to the lower redistribution layer;
a plurality of posts disposed adjacent to the lower chip structure and comprising a lower metal layer disposed on the lower redistribution layer and an upper metal layer disposed on the lower metal layer;
an encapsulant covering respective side surfaces of the lower chip structure and the plurality of posts;
a heat dissipation member disposed on the encapsulant and vertically overlapping at least a portion of the lower chip structure;
an upper chip structure disposed on one side of the heat dissipation member, vertically overlapping at least a portion of the plurality of posts, and electrically connected to the lower redistribution layer through the plurality of posts; and
a plurality of external connection bumps disposed below the lower redistribution structure and electrically connected to the lower redistribution layer,
wherein the lower metal layer and the upper metal layer comprise different metals.

2. The semiconductor package of claim 1, wherein the lower metal layer comprises a first metal, and
the upper metal layer comprises a second metal having a diffusion coefficient lower than a diffusion coefficient of the first metal in silicon.

3. The semiconductor package of claim 1, wherein a height of the lower metal layer is about equal to or greater than a height of the upper metal layer.

4. The semiconductor package of claim 3, wherein the height of the upper metal layer is about 3 μm or more.

5. The semiconductor package of claim 3, wherein the plurality of posts further comprise a seed layer disposed between the lower metal layer and the lower redistribution layer, and
the height of the upper metal layer is greater than a height of the seed layer.

6. The semiconductor package of claim 1, further comprising:
a plurality of lower connection bumps disposed between the lower chip structure and the lower redistribution structure; and
a plurality of upper connection bumps disposed between the upper chip structure and the plurality of posts.

7. The semiconductor package of claim 1, wherein the heat dissipation member comprises a thermal interface material disposed on the lower chip structure and a heat slug disposed on the thermal interface material.

8. The semiconductor package of claim 1, wherein the lower chip structure comprises a logic chip, and
the upper chip structure comprises a memory chip.

9. The semiconductor package of claim 1, wherein the lower chip structure comprises a plurality of semiconductor chips stacked vertically, and a molding member covering at least a portion of the plurality of semiconductor chips.

10. The semiconductor package of claim 9, wherein at least one of the plurality of semiconductor chips comprises a plurality of through-vias electrically connecting the plurality of semiconductor chips.

11. The semiconductor package of claim 1, wherein the upper chip structure comprises a substrate, a plurality of semiconductor chips vertically stacked on the substrate, and a molding member covering at least a portion of the plurality of semiconductor chips.

12. The semiconductor package of claim 11, wherein the upper chip structure further comprises a bonding wire electrically connecting the plurality of semiconductor chips to the substrate.

13. The semiconductor package of claim 1, wherein on a plane, the heat dissipation member surrounds at least three surfaces of the upper chip structure.

14. The semiconductor package of claim 1, wherein the plurality of posts comprise a plurality of dummy posts not vertically overlapping the upper chip structure.

15. The semiconductor package of claim 1, further comprising:
an upper redistribution structure disposed below the heat dissipation member and the upper chip structure, and comprising an upper redistribution layer electrically connecting the plurality of posts and the upper chip structure.

16. The semiconductor package of claim 15, wherein the plurality of posts comprise a plurality of first posts overlapping the upper chip structure and a plurality of second posts not overlapping the upper chip structure,
wherein at least a portion of the second posts is electrically connected to the upper chip structure by the upper redistribution layer.

17. A semiconductor package, comprising:
a lower redistribution structure;
a lower chip structure disposed on the lower redistribution structure;
a plurality of posts disposed adjacent to the lower chip structure and comprising a lower metal layer and an upper metal layer disposed on the lower metal layer;
an encapsulant covering at least portions of the lower chip structure and the plurality of posts;
a heat dissipation member disposed on the encapsulant and vertically overlapping at least a portion of the lower chip structure;
an upper chip structure disposed on one side of the heat dissipation member and vertically overlapping at least portions of the plurality of posts; and
a plurality of upper connection bumps disposed between the upper chip structure and the plurality of posts,
wherein a side surface of the lower metal layer and a side surface of the upper metal layer are in contact with the encapsulant, and
an upper surface of the upper metal layer is in contact with the upper connection bumps.

18. The semiconductor package of claim 17, wherein the side surface of the lower metal layer and the side surface of the upper metal layer define a same flat surface.

19. The semiconductor package of claim 17, wherein the upper surface of the upper metal layer is substantially coplanar with an upper surface of the encapsulant and an upper surface of the lower chip structure.

20. A semiconductor package, comprising:
a lower redistribution structure;
a lower chip structure disposed on the lower redistribution structure;
a plurality of posts disposed adjacent to the lower chip structure and comprising a lower metal layer and an upper metal layer disposed on the lower metal layer;
an encapsulant covering at least portions of the lower chip structure and the plurality of posts;
a heat dissipation member disposed on the encapsulant and vertically overlapping at least a portion of the lower chip structure; and
an upper chip structure disposed on one side of the heat dissipation member and vertically overlapping at least portions of the plurality of posts,
wherein a width of the lower metal layer is substantially equal to a width of the upper metal layer.
